(19) United States
(12) Patent Application Publication
(10) Pub. No.: US 2016/0181294 A1
(43) Pub. Date: Jun. 23, 2016

(54) BACKSIDE ILLUMINATED IMAGE SENSOR AND MANUFACTURING METHOD THEREFOR

(71) Applicant: GALAXYCORE SHANGHAI LIMITED CORPORATION, Shanghai (CN)

(72) Inventor: Lixin ZHAO, Shanghai (CN)

(73) Assignee: Galaxycore Shanghai Limited Corporation, Shanghai (CN)

(21) Appl. No.: 14/904,911

(22) PCT Filed: Jul. 10, 2014
(86) PCT No.: PCT/CN2014/081956

§ 371 Date: Jan. 13, 2016

(30) Foreign Application Priority Data
Jul. 15, 2013 (CN) 201310294893.0

(51) Int. Cl. H01L 27/146

(52) U.S. Cl. CPC H01L 27/1462; H01L 27/1464; H01L 27/14627; H01L 27/14621; H01L 27/14645; H01L 27/14685; H01L 27/14689

(57) ABSTRACT

The present invention relates to a backside illuminated image sensor and a manufacturing method therefor. The backside illuminated image sensor comprises: a silicon wafer layer, which comprises a photodiode for generating an electrical signal by sensing light, wherein the silicon wafer layer is provided with a front surface and a back surface; a rear-end layer, which is provided on the front surface of the silicon wafer layer, wherein the rear-end layer comprises a transistor gate, a gate oxide layer, a wire layer and a dielectric layer; a light incidence layer, which comprises a micro-lens layer and a light filtering film layer, wherein the light incidence layer is provided on the back surface of the silicon wafer layer; and the rear-end layer further comprises: a light-absorbing layer, which is provided in a pre-set position of the rear-end layer, wherein the light-absorbing layer is used for absorbing a light ray transmitted from the silicon wafer layer. The light-absorbing layer employed in the present invention absorbs a light ray transmitted from a device layer, thereby greatly reducing the chance that the transmitted light ray is reflected to other pixels, so as to reduce the mutual crosstalk between adjacent pixels.

### CROSS-REFERENCE TO RELATED APPLICATIONS

This application is a National Stage application of International Application No. PCT/CN2014/081956, filed Jul. 10, 2014, titled “Backlit Image Sensor and Manufacturing Method Therefor,” which claims priority to Chinese Patent Application No. CN 201310294893.0, filed Jul. 15, 2013, titled “Backside-Illuminated Image Sensor and Manufacturing Method Thereof,” both of which are hereby incorporated by reference in their entirety.

### TECHNICAL FIELD

The present invention relates to the field of image sensors, and particularly to a backside illuminated image sensor and a manufacturing method therefor.

### BACKGROUND

In conventional image sensors, during the transmission of a light ray, the light ray first passes through metal interconnect layers and further enters into a photosensitive diode. Since the photosensitive diode is located behind circuit transistors, the amount of light entered can be influenced due to the block of at least one layer of inter-layer metal layers of the metal interconnect layers and the associated gate structure. For this purpose, as the image sensor technology develops, backside illuminated image sensor are produced. The so-called backside illuminated image sensor is a image sensor that, compared with conventional frontside illuminated image sensors, reverses the orientation of the image sensor so that a light ray enters into a photosensitive diode first, which results in an increased amount of light sensed and an significantly improved imaging quality in low illumination conditions.

Compared with the conventional frontside illuminated CMOS image sensor, the backside illuminated CMOS image sensor (complementary metal oxide semiconductor) is not influenced by the blocking of frontside circuits of an image sensor chip, thereby allowing for improved device performance by reducing the amount of incident light lost when encountering with metal wires and other media, since the backside illuminated CMOS image sensor senses light from the backside of the image sensor chip. With the same chip size, it further has the advantages of larger photosensitive area, higher image brightness, and clearer image in dark light. However, as shown in FIG. 1, the light ray may crosstalk and thus undergoes losses due to diffusion of light ray “L” to an adjacent image sensor chip or refraction of the light ray “L” by metal interconnect layers provided outside the front side of the image sensor. Crosstalk among pixels is a relatively big problem of backside illuminated image sensors.

As shown in FIG. 1, the backside illuminated image sensor in the related art mainly comprises: (1) an electronic device layer 1 mainly comprising a photodiode (PD) 101 for sensing light and several transistor circuits 102 for signal transmission and processing, which conventionally usually employ a 3T, 4T or 5T structure, the electronic device layer 1 being provided with a back surface for receiving incident light and an opposite front surface for emergent light; (2) a rear-end circuit layer 2 composed of a plurality of metal interconnect layers 203 and 204, a metal conductive pillar 205 electrically connected to the metal interconnect layers, and a dielectric layer 201, wherein the rear-end circuit layer 2 is located on the front side of the electronic device layer and functions mainly to output an electrical signal of the device layer via the manufactured circuit of metal interconnect layers; and (3) a light incidence layer 3 mainly comprising a light filtering film layer and a micro-lens layer that are sequentially provided on the back side of the electronic device layer 1, wherein this layer functions mainly to converge and filter the incident light to obtain a monochromatic light and then to introduce the light into a photosensitive region of the electronic device layer. Since the thickness of electronic device layer is relatively small (about 2 um) generally, a part of the light with a relatively long wavelength can travel through the electronic device layer, and the transmitted light can also be reflected back to the electronic device layer by the rear-end circuit layer; and depending on the angle, the reflected light may be directed to an adjacent photosensitive region, causing crosstalk of signals between adjacent pixel units and consequently reduction of the image sharpness and decrease of the image quality.

In summary, to provide a backside illuminated image sensor which effectively reduces the crosstalk between adjacent pixel units of a image sensor chip and a manufacturing method therefor has become an urgent problem to be solved by a person skilled in the art.

The information disclosed in the part of background of the invention only aims to deepen the understanding of general background of the invention, and should not be considered to admit or suggest in any form that the information constitutes the related art that has been known to a person skilled in the art.

### SUMMARY OF THE INVENTION

In order to solve the problems existing in the related art, the present invention provides a mechanism which uses a light-absorbing layer to absorb a light ray transmitted from a device layer so as to greatly reduce the chance that the transmitted light ray is reflected to other pixels, so as to reduce the mutual crosstalk between adjacent pixels.

In order to achieve the above-mentioned purpose, the present invention provides a backside illuminated image sensor, comprising:

a silicon wafer layer, which comprises a photodiode for generating an electrical signal by sensing light, wherein said silicon wafer layer is provided with a front surface and a back surface; a rear-end layer, which is provided on the front surface of said silicon wafer layer, said rear-end layer comprises a transistor gate, a gate oxide layer, a wire layer and a dielectric layer; and a light incidence layer, which comprises a micro-lens layer and a light filtering film layer, wherein said light incidence layer is provided on the back surface of said silicon wafer layer. The rear-end layer further comprises: a light-absorbing layer, which is provided in a pre-set position in the rear-end layer, wherein said light-absorbing layer is used for absorbing a light ray transmitted from the silicon wafer layer.

Preferably, the light-absorbing layer is provided in a pre-set region inside the dielectric layer of said rear-end layer.

Preferably, said light-absorbing layer is provided in a pre-set region between the front surface of said silicon wafer layer and said dielectric layer.

Preferably, said light-absorbing layer and said dielectric layer are the same structural layer, i.e., said dielectric layer is composed of a light-absorbing material so that said dielectric layer has a light-absorbing function and an insulation function at the same time.

Preferably, said light-absorbing layer is provided below the front surface of the silicon wafer layer in a position where said photodiode is located, and the cross sectional area of said light-absorbing layer is not less than the cross sectional area of said photodiode.

Preferably, said light-absorbing material is a material whose light absorbance for light in a detection wave band of the sensor is between 50% and 100%.

Preferably, said light-absorbing material is graphite, carbon or chromium trioxide.

The present invention further provides a method for manufacturing a backside illuminated image sensor, comprising: manufacturing a silicon wafer layer that comprises a photodiode and a transistor circuit, wherein said silicon wafer layer is provided with a front surface and a back surface; manufacturing a rear-end layer, wherein said rear-end layer is formed on the front surface of said silicon wafer layer, and said rear-end layer comprises a transistor gate, a gate oxide layer, a wire layer and a dielectric layer; forming a light-absorbing layer in a pre-set position in said rear-end layer; and manufacturing on the back surface of the silicon wafer layer a light incidence layer that comprises a light filtering film layer and a micro-lens layer.

Preferably, the step of manufacturing the light-absorbing layer comprises: depositing one light-absorbing layer on the front surface of said silicon wafer layer, removing light-absorbing material outside a pre-set region, and then forming a dielectric layer on the front surface of said silicon wafer layer and said light-absorbing layer.

Preferably, in the step of manufacturing the light-absorbing layer, after a dielectric layer with a pre-set thickness is formed, a groove with a pre-set depth is formed on a lower surface of said dielectric layer with the pre-set thickness, a light-absorbing material is filled in the groove to form the light-absorbing layer after smooth processing, and then the dielectric layer is continued formed on the lower surface of said dielectric layer with the pre-set thickness.

Preferably, in the steps of manufacturing the light-absorbing layer, after a dielectric layer with a pre-set thickness is formed, one light-absorbing layer is deposited on a lower surface of said dielectric layer with the pre-set thickness, the light-absorbing material outside the pre-set region is removed, and then subsequent dielectric layer is continued formed.

Preferably, in the step of manufacturing the light-absorbing layer, said light-absorbing layer and said dielectric layer are the same structural layer, i.e., said dielectric layer is composed of a light-absorbing material so that said dielectric layer has a light-absorbing function and an insulation function at the same time.

Preferably, said light-absorbing layer is provided below the front surface of the silicon wafer layer in a position where said photodiode is located, and the cross sectional area of the light-absorbing layer is not less than the cross sectional area of the photodiode.

Preferably, said light-absorbing material is a material whose light absorbance for a light in a detection wave band of the sensor is between 50% and 100%.

Preferably, said light-absorbing material is graphite, carbon or chromium trioxide.

The beneficial effects of the present invention are as follows: the light-absorbing layer absorbs a light ray transmitted from a device layer, thereby being able to greatly reduce the chance that the transmitted light ray is reflected to other pixels, so as to reduce the mutual crosstalk between adjacent pixels.

### BRIEF DESCRIPTION OF THE DRAWINGS

Other features and advantages of the present invention will become apparent or can be set forth more specifically from the drawings and certain embodiments below for explaining some principles of the present invention together with the drawings.

FIG. 1 is a sectional view of a backside illuminated image sensor in the related art.

FIG. 2 is a sectional view of a structure of the present invention.

FIG. 3 is a sectional view of a structure of a first embodiment of the present invention.

FIGS. 4A and 4B are sectional views of a structure of a second embodiment of the present invention.

FIG. 5 is a sectional view of a structure of a third embodiment of the present invention.

FIG. 6 is a schematic diagram of the step of forming a silicon wafer layer in the manufacturing method of the present invention.

FIG. 7 is a schematic diagram of steps of forming a pre-set thickness in the manufacturing method of the present invention.

FIG. 8 is a schematic diagram of the step of forming a pre-set depth in the manufacturing method of the present invention.

FIG. 9 is a schematic diagram of the step of forming a light-absorbing layer in the manufacturing method of the present invention.

FIG. 10 is a schematic diagram of the step of continuing forming a rear-end layer in the manufacturing method of the present invention.

FIG. 11 is a schematic diagram of the step of forming a light incidence layer in the manufacturing method of the present invention.

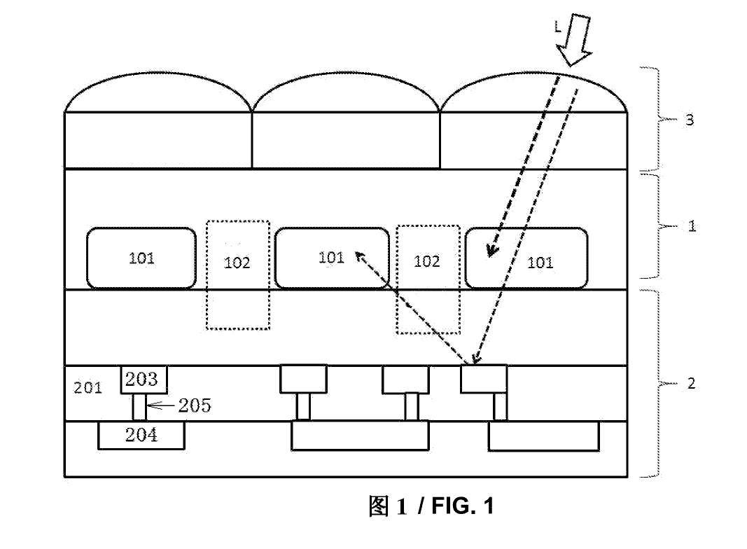

It should be understood that specific structures of the present invention are not necessarily illustrated to scale in the drawings, and illustrative features for explaining some principles of the present invention are also drawn in a slightly simplified manner in the drawings. Specific design characteristics of the present invention disclosed herein include that the specific size, direction, position and appearance that will be partially determined by the particular application and utilization environment.

Throughout the drawings, the same reference numerals represent the same or equivalent parts of the present invention.

### DETAILED DESCRIPTION

In the following description, numerous specific details are set forth in order to fully understand the present invention. However, the present invention can be implemented in numerous other ways that are different from those described herein, and a person skilled in the art can make similar deviations without departing from the spirit of the present invention, and therefore the present invention is not limited to the particular embodiments disclosed below.

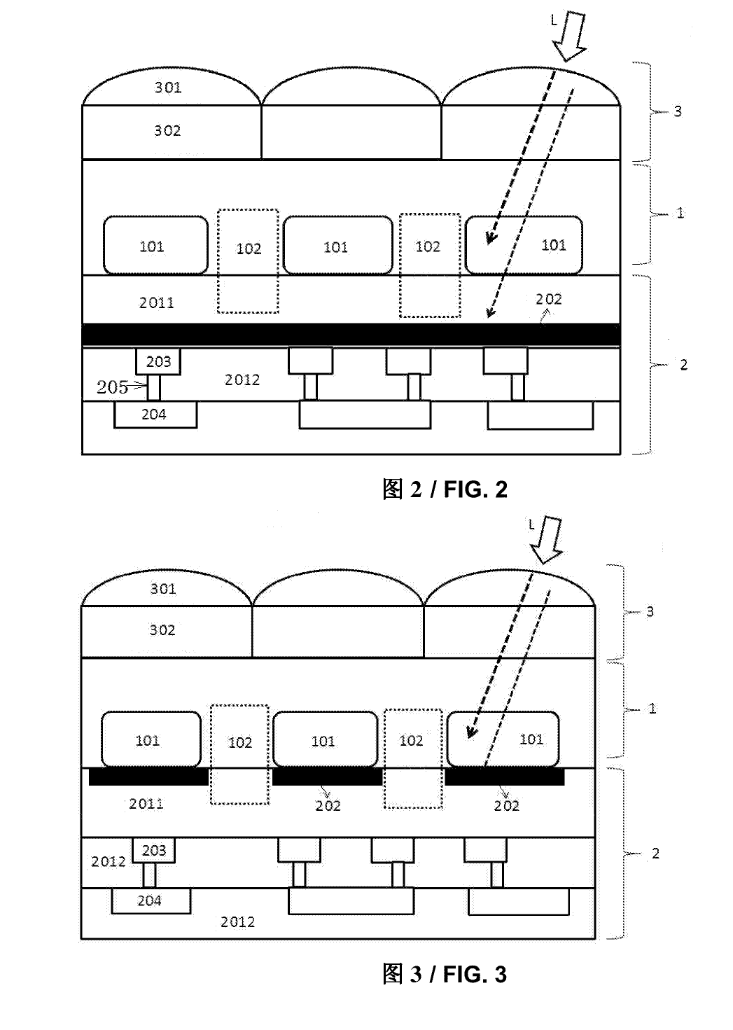

The particular embodiments of the present invention will be described below in combination with the drawings. Referring to FIG. 2, the present invention provides a backside illuminated image sensor, comprising:

a silicon wafer layer 1, which comprises a photodiode 101 for generating an electrical signal by sensing light, wherein said silicon wafer layer 1 is provided with a front surface and a back surface, and the silicon wafer layer 1 further comprises a transistor 102 for transmitting and processing said electrical signal;

a rear-end layer 2, which is provided on the front surface of the silicon wafer layer, wherein said rear-end layer comprises transistor wire layers 203 and 204, dielectric layers 2011 and 2012 and a gate and a gate oxide layer (not shown); and

a light incidence layer 3, which comprises a micro-lens layer 301 and a light filtering film layer 302, wherein said light incidence layer is provided on the back surface of the silicon wafer layer 1;

the rear-end layer further comprises a light-absorbing layer 202, which is provided in a pre-set position in the rear-end layer 2, wherein said light-absorbing layer 202 is used for absorbing a light ray L transmitted from the silicon wafer layer 1, said light-absorbing layer 202 can be provided in a pre-set region between the front surface of the silicon wafer layer 1 and said dielectric layer (2011 or 2012), said light-absorbing layer 202 can also be provided in a pre-set region inside a dielectric layer 201 of the rear-end layer 2, and said light-absorbing layer 202 and the dielectric layer 2011 can also be the same structural layer, i.e., said dielectric layer 2011 can be composed of a light-absorbing material so that said dielectric layer has a light-absorbing function and an insulation function at the same time.

Preferably, said light-absorbing layer 202 is provided below the front surface of the silicon wafer layer in a position where the photodiode 101 is located, and the cross sectional area of said light-absorbing layer 202 is not less than the cross sectional area of the photodiode 101.

With regard to the present invention, the light-absorbing material employed by said light-absorbing layer 202 is a material whose light absorbance for the light in the detection waveband of the sensor is between 50% and 100%. Said light-absorbing material can be graphite, carbon or chromium trioxide.

Referring to FIG. 3, in a first embodiment of the present invention, said backside illuminated image sensor comprises: a silicon wafer layer 1, which comprises a photodiode 101 for generating an electrical signal by sensing light, wherein said silicon wafer layer 1 is provided with a front surface and a back surface, and the silicon wafer layer 1 further comprises a transistor 102 for transmitting and processing said electrical signal; a rear-end layer 2, which is provided on the front surface of said silicon wafer layer, wherein said rear-end layer comprises transistor wire layers 203 and 204, dielectric layers 2011 and 2012 and a gate and gate oxide layer (not shown in the figures); and a light incidence layer 3, which comprises a micro-lens layer 301 and a light filtering film layer 302, wherein said light incidence layer is provided on the back surface of the silicon wafer layer 1. The rear-end layer further comprises a light-absorbing layer 202, wherein said light-absorbing layer 202 is used for absorbing a light ray L transmitted from the silicon wafer layer 1. The light-absorbing layer 202 is provided between the front surface of said silicon wafer layer 1 and said dielectric layer 2011, and said light-absorbing layer covers a region of the front surface of the silicon wafer layer 1 corresponding to said photodiode 101.

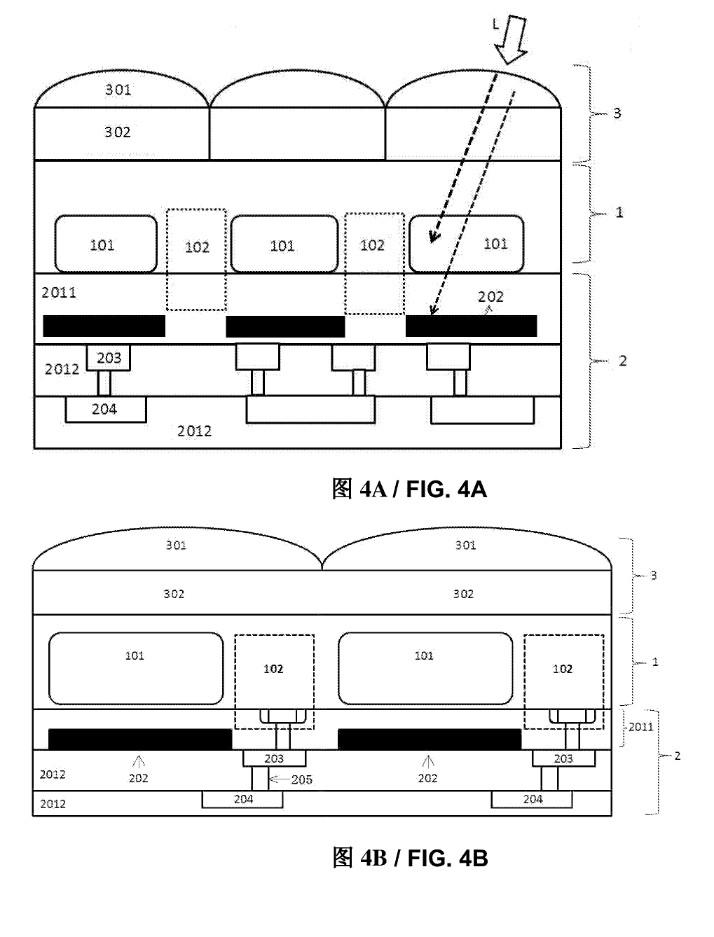

Referring to FIGS. 4A and 4B, in a second embodiment of the present invention, said light-absorbing layer 202 is provided in the pre-set region inside the dielectric layer 2011 of said rear-end layer 2, with other features being the same as those in the first embodiment.

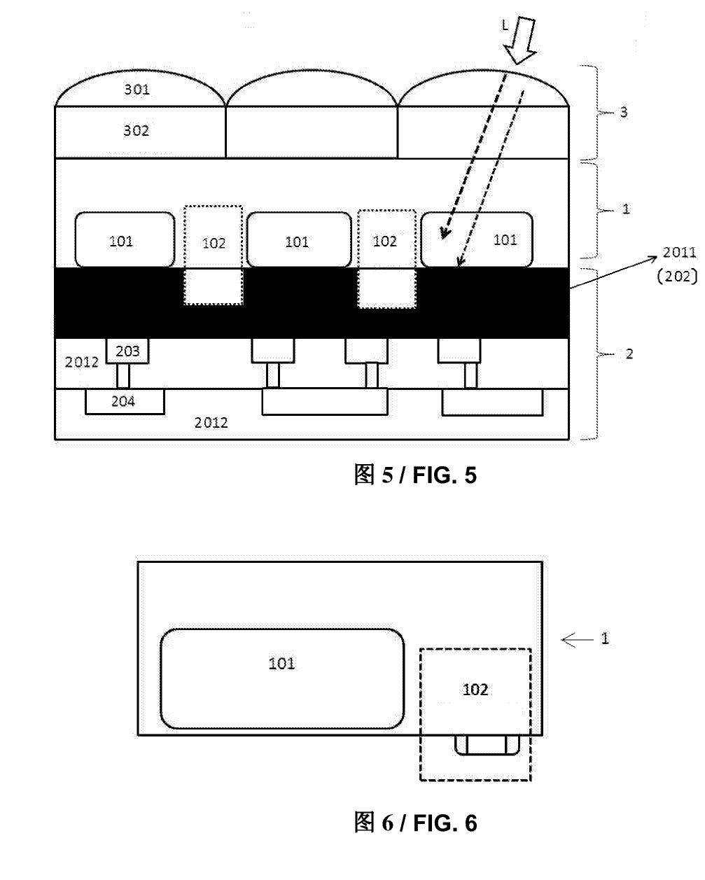

Referring to FIG. 5, in a third embodiment of the present invention, said light-absorbing layer 202 and said dielectric layer 2011 are the same structural layer, i.e., said dielectric layer is composed of a light-absorbing material so that the dielectric layer has a light-absorbing function and an insulation function at the same time, with other features being the same as those in the first embodiment.

The present invention further provides a method for manufacturing a backside illuminated image sensor:

a first embodiment: with reference to the accompanying figures:

as shown in FIG. 2, the manufacture of a silicon wafer layer 1 that comprises a plurality of pixel units is provided, wherein each pixel unit contains a photodiode 101 and several transistor circuits 102, and said silicon wafer layer 1 is provided with a front surface for emergent light and an opposite back surface for receiving incident light; and

the rear-end layer 2 is manufactured by deposition by means of a thermal oxidation process or semiconductor processes.

Firstly, as shown in FIG. 2, a first dielectric layer 2011 is formed by deposition on the front surface of the silicon wafer layer 1, then after a planarization process, a light-absorbing layer 202 completely covering the first dielectric layer 2011 is formed on a surface of the first dielectric layer 2011 away from the silicon wafer layer 1 by deposition. The available deposition may be chemical vapour deposition or physical vapour deposition etc. The light-absorbing layer is planarized and then a second dielectric layer 2012 is deposited again on the light-absorbing layer 202. A plurality of through-holes are formed by etching in the second dielectric layer 2012 by means of masking and patterning related regions, and conductive pillars 205 are formed by depositing a conductive material in the through-holes. Wire layers 203 are correspondingly formed in the second dielectric layer 2012; hereafter, a multiple layer structure of a conductive layer 204 can be formed correspondingly. In the steps above, the transistor circuits 102 in the silicon wafer layer 1 are electrically connected to the exterior of the second dielectric layer 2012 via wire by applying a through-hole process to the first dielectric layer 2011, the light-absorbing layer 202, the second dielectric layer 2012 etc. Furthermore, a light incidence layer comprising a light filtering film layer and a micro-lens layer is manufactured in sequence on the back surface of said silicon wafer layer 1. In the present embodiment, the light-absorbing layer completely covers and corresponds to a surface of the first dielectric layer, and particularly, multiple dielectric layers of a third dielectric layer and a fourth dielectric layer etc. can be manufactured by deposition exterior the second dielectric layer 2012 according to the specific different processes, so as to meet the requirement of the specific image sensor.

A second embodiment: as shown in FIG. 4, the steps in the present embodiment are substantially the same as those in the first embodiment, with the differences being: after the light-absorbing layer 202 completely covering the first dielectric layer 2011 is formed by deposition on a surface of the first dielectric layer 2011 away from the silicon wafer layer 1, the light-absorbing layer 202 corresponding to non-photosensitive regions of the silicon wafer layer 1 is etched, exposing the first dielectric layer 2011. The resulting light-absorbing layer 202 corresponds only to photosensitive regions of the silicon wafer layer 1, and the cross sectional area of the light-absorbing layer 202 is not less than the cross sectional area of the photodiode 101.

A third embodiment: as shown in FIG. 3, firstly, the light-absorbing layer 202 is formed by deposition on the front surface of the silicon wafer layer 1. The light-absorbing layer 202 corresponding to the non-photosensitive regions of the silicon wafer layer 1 is etched by means of masking and patterning related regions, exposing the front surface of the silicon wafer layer 1. Then a first dielectric layer 2011 surface covering the light-absorbing layer is formed by deposition correspondingly, and a conductive layer 203 is formed by means of the through-hole process and by depositing a conductive material; hereafter, a structure of a plurality of conductive layers 204 can be formed correspondingly, and particularly, multiple dielectric layers of a third dielectric layer and a fourth dielectric layer etc. can be manufactured by deposition exterior the second dielectric layer 2012 according to the specific different processes, so as to meet the requirement of the specific image sensor. In the steps above, the transistor circuits 102 in the silicon wafer layer 1 are electrically connected to the exterior of the outermost dielectric layer via wire by applying through-hole process to the first dielectric layer 2011, the light-absorbing layer 202, and the multiple dielectric layers that may be arranged subsequently. A light incidence layer comprising a light filtering film layer and a micro-lens layer is manufactured on the back surface of the silicon wafer layer 1.

In this embodiment, the light-absorbing layer is deposited in contact with the silicon wafer layer 1, the regions of the silicon wafer layer corresponds to the front surface of photosensitive regions (photodiode regions) of the silicon wafer layer 1 where the photodiodes are located, and the cross sectional area of the light-absorbing layer is not less than the cross sectional area of the photodiode.

A fourth embodiment: as shown in FIG. 5, the steps in the present embodiment are substantially the same as those in the third embodiment, with the difference being: a groove structure corresponding to the non-photosensitive region of the silicon wafer layer 1 is formed when the light-absorbing layer corresponding to the non-photosensitive region of the silicon wafer layer 1 is etched.

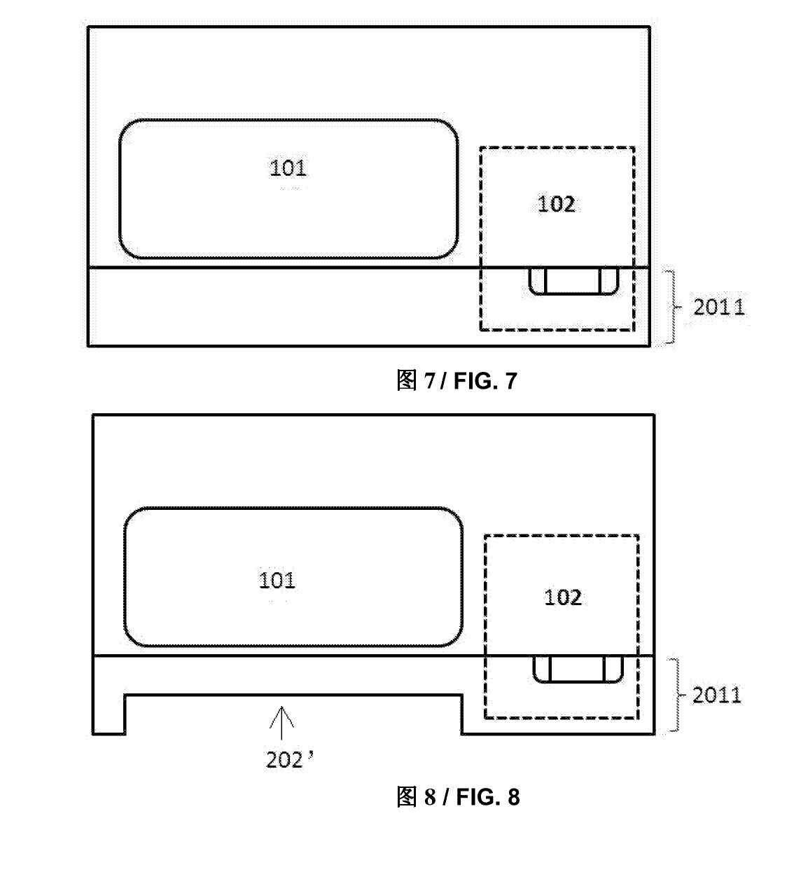

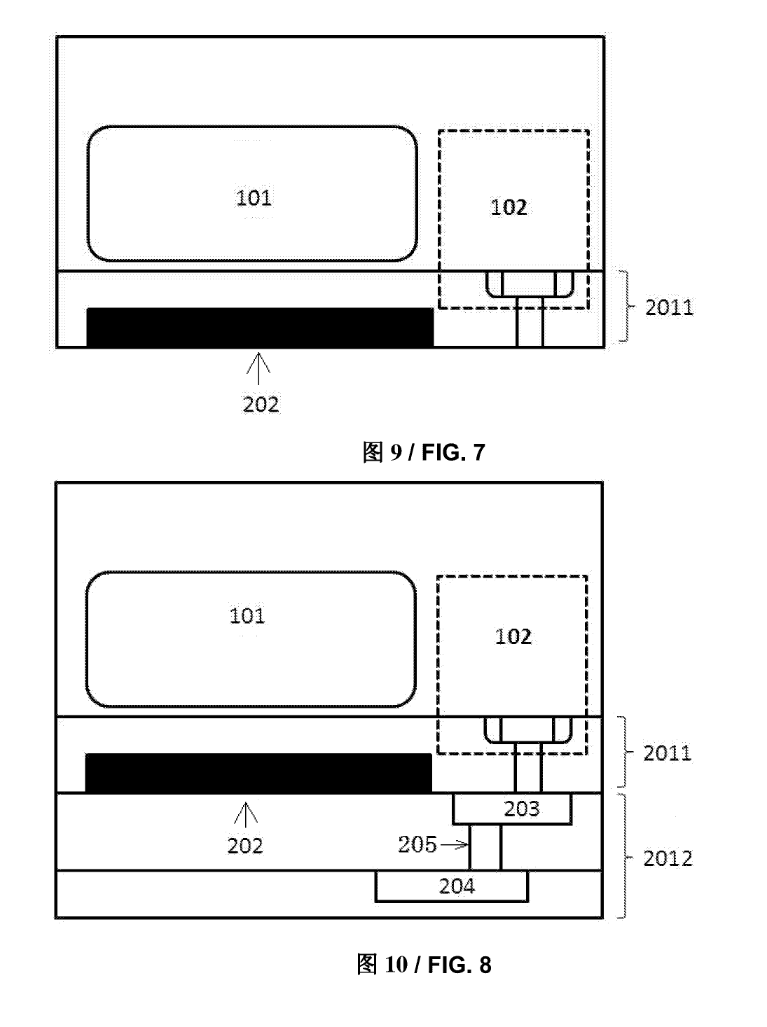

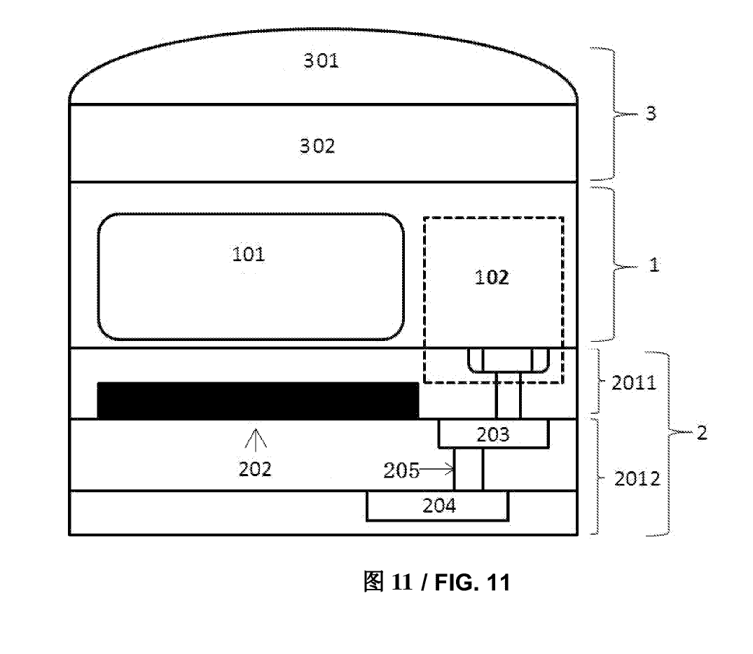

A fifth embodiment: as shown in FIGS. 6 to 11: a method for manufacturing a backside illuminated image sensor comprises:

providing a silicon wafer layer 1 that comprises a plurality of pixel units, wherein each pixel unit contains a photodiode 101 and several transistor circuits 102, and said silicon wafer layer 1 is provided with a front surface for emergent light and an opposite back surface for receiving incident light; and

manufacturing the rear-end layer 2 by deposition by means of semiconductor processes;

firstly, a first dielectric layer 2011 is formed by deposition on the front surface of the silicon wafer layer 1, and then after a planarization process, by means of masking, patterning and etching the first dielectric layer 2011 on one surface of the first dielectric layer 2011 away from the silicon wafer layer 1, a corresponding structure of groove 202′ is formed. The region extent of the structure of groove 202′ corresponds to the photosensitive regions (photodiode regions) of the silicon wafer layer 1. A corresponding light-absorbing material is deposited in the groove 202′ to form a corresponding light-absorbing layer 202. The available deposition may be chemical vapour deposition or physical vapour deposition etc. The light-absorbing layer 202 is planarized and then a second dielectric layer 2012 is deposited again on the light-absorbing layer 202. A plurality of through-holes are formed by etching in the second dielectric layer 2012 by means of masking and patterning related regions, conductive pillars 205 are formed by depositing conductive material in the through-holes, and a wire layer 203 is correspondingly formed in the second dielectric layer 2012; hereafter, a multiple layer structure of conductive layers can be formed correspondingly. In the steps above, the transistor circuits 102 in the silicon wafer layer 1 are electrically connected to the exterior of the second dielectric layer 2012 via wire by applying through-hole process to the first dielectric layer 2011, the light-absorbing layer 202, the second dielectric layer 2012 etc., and particularly, multiple dielectric layers of a third dielectric layer and a fourth dielectric layer etc. can be manufactured by deposition exterior the second dielectric layer 2012 according to the specific different processes, so as to meet the requirement of the specific image sensor. Finally, the transistor circuits 102 in the silicon wafer layer 1 are electrically connected to the exterior of the outermost dielectric layer via wire by applying the through-hole process; and furthermore, a light incidence layer 3 comprising a light filtering film layer 302 and a micro-lens layer 301 is manufactured in sequence on the back surface of the silicon wafer layer 1. In the present embodiment, the light-absorbing layer 202 corresponds only to the photosensitive region of the silicon wafer layer 1, and the cross sectional area of the light-absorbing layer 202 is not less than the cross sectional area of the photodiode 101.

In the present invention, the light-absorbing material employed by the light-absorbing layer 202 is a material whose light absorbance for a light in the detection wave band of the sensor is between 50% and 100%, said light-absorbing material can be graphite, carbon or chromium trioxide.

It is particularly pointed out that forming the multiple layer structure of conductive layers in the first embodiment to the fifth embodiment can comprise a damascene process which deposits dielectric layers and forms through-holes in the dielectric layers via through-hole process and then fills copper (Cu); it can also comprise steps of firstly depositing aluminium (Al) layers, then etching the aluminium layers, retaining the regions for connecting and then depositing dielectric layers.

The main technical solution of the present invention is the structure of the light-absorbing layer, which is selectively provided in different steps, in the backside illuminated image sensor, and providing the light-absorbing layer in different steps in the process flow of the backside illuminated image sensor. Since different steps and process are used to realize the arrangement of the light-absorbing layer in the first embodiment to the fifth embodiment, the present invention has prominent substantive features and significant characteristics. The light-absorbing layer achieves a technical effect of reducing and even preventing light ray crosstalk. The light-absorbing layer absorbs light rays transmitted from a device layer, thereby greatly reducing the chance that the transmitted light ray is reflected to other pixels, so that the mutual crosstalk between adjacent pixels is reduced.

The above-mentioned embodiments are used for illustratively explaining the principles of the present invention and the efficacy thereof; however, the present invention is not limited to the above-mentioned embodiments. A person skilled in the art can make modifications to the above-mentioned embodiments within the scope of the claims without departing from the spirit and scope of the present invention. Therefore, the scope of the present invention shall be defined by the claims of the present invention.

1. A backside illuminated image sensor, comprising:
a silicon wafer layer, which comprises a photodiode for generating an electrical signal by sensing light, said silicon wafer layer is provided with a front surface and a back surface;
a rear-end layer, which is provided on the front surface of said silicon wafer layer, said rear-end layer comprises a transistor gate, a gate oxide layer, a wire layer and a dielectric layer; and
a light incidence layer, which comprises a micro-lens layer and a light filtering film layer, said light incidence layer is provided on the back surface of said silicon wafer layer;
wherein said rear-end layer further comprises:
a light-absorbing layer, which is provided in a pre-set position in said rear-end layer, said light-absorbing layer is used, at least in part, for absorbing a light ray transmitted from the silicon wafer layer.

2. The backside illuminated image sensor according to claim 1 wherein said light-absorbing layer is provided in a pre-set region inside the dielectric layer of said rear-end layer.

3. The backside illuminated image sensor according to claim 1 wherein said light-absorbing layer is provided in a pre-set region between the front surface of said silicon wafer layer and said dielectric layer.

4. The backside illuminated image sensor according to claim 1 wherein said light-absorbing layer and said dielectric layer are the same structural layer, wherein said dielectric layer comprises a light-absorbing material, and wherein that said dielectric layer is configured to simultaneously absorb light and insulate.

5. The backside illuminated image sensor according to claim 1 wherein said light-absorbing layer is provided below the front surface of the silicon wafer layer in a position where said photodiode is located, and wherein the cross sectional area of said light-absorbing layer is more than or equal to the cross sectional area of said photodiode.

6. The backside illuminated image sensor according to claim 4 wherein said light-absorbing material comprises a material whose light absorbance for light in a detection wave band of the sensor is between 50% and 100%.

7. The backside illuminated image sensor according to claim 4 wherein said light-absorbing material comprises graphite, carbon or chromium trioxide.

8. A method for manufacturing a backside illuminated image sensor, the method comprising:
manufacturing a silicon wafer layer that comprises a photodiode and a transistor circuit, said silicon wafer layer provided with a front surface and a back surface;
manufacturing a rear-end layer, wherein said rear-end layer is formed on the front surface of said silicon wafer layer, and said rear-end layer comprises a transistor gate, a gate oxide layer, a wire layer and a dielectric layer;
forming a light-absorbing layer in a pre-set position in said rear-end layer; and
manufacturing, on the back surface of said silicon wafer layer, a light incidence layer that comprises a light filtering film layer and a micro-lens layer.

9. The method for manufacturing the backside illuminated image sensor according to claim 8, wherein forming the light-absorbing layer comprises:
depositing a light-absorbing layer material on the front surface of said silicon wafer layer,
removing light-absorbing material outside a pre-set region, and
forming the dielectric layer on the front surface of said silicon wafer layer and said light-absorbing layer.

10. The method for manufacturing the backside illuminated image sensor according to claim 8, wherein forming the light-absorbing layer further comprises:
forming a dielectric layer with a pre-set thickness,
forming a groove with a pre-set depth is formed on a lower surface of said dielectric layer with the pre-set thickness, and
filling a light-absorbing material in the groove to form the light-absorbing layer after a smooth processing procedure,
wherein the dielectric layer is continued formed on the lower surface of said dielectric layer with the pre-set thickness.

11. The method for manufacturing the backside illuminated image sensor according to claim 8, wherein forming the light-absorbing layer further comprises:
forming a dielectric layer with a pre-set thickness,
depositing a light-absorbing layer material on a lower surface of said dielectric layer with the pre-set thickness, and
removing the light-absorbing material outside a pre-set region,
wherein a subsequent dielectric layer is continued formed.

12. The method for manufacturing the backside illuminated image sensor according to claim 8, wherein said light-absorbing layer and said dielectric layer are the same structural layer, and wherein said dielectric layer is composed of a light-absorbing material so that said dielectric layer is configured to simultaneously absorb light and insulate.

13. The method for manufacturing the backside illuminated image sensor according to claim 8, wherein said light-absorbing layer is provided below the front surface of the silicon wafer layer in a position where said photodiode is located, and wherein the cross sectional area of the light-absorbing layer is more than or equal to the cross sectional area of the photodiode.

14. The method for manufacturing the backside illuminated image sensor according to claim 12, wherein said light-absorbing material comprises a material whose light absorbance for a light in a detection wave band of the sensor is between 50% and 100%.

15. The method for manufacturing the backside illuminated image sensor according to claim 12, wherein said light-absorbing material comprises graphite, carbon or chromium trioxide.
